(19) United States
(12) Patent Application Publication
(10) Pub. No.: US 2026/0082562 A1
(43) Pub. Date: Mar. 19, 2026

(54) METHOD OF MANUFACTURING SEMICONDUCTOR DEVICE

(71) Applicant: Kioxia Corporation, Tokyo (JP)

(72) Inventor: Shunsuke HAZUE, Yokkaichi Mie (JP)

(21) Appl. No.: 19/075,595

(22) Filed: Mar. 10, 2025

(30) Foreign Application Priority Data
Sep. 13, 2024 (JP) 2024-159618

(51) Int. Cl. H10B 43/27; H01L 23/00; H01L 25/00; H01L 25/065; H01L 25/18; H10B 43/10; H10B 43/35; H10B 80/00

(52) U.S. Cl. CPC H10B 43/27; H10B 43/10; H10B 43/35; H10B 80/00; H10W 90/00; H10W 80/312; H10W 80/327; H10W 90/792

(57) ABSTRACT

A method of manufacturing a semiconductor device includes stacking first insulating films in alternation with sacrificial layers along a first direction, then forming first and second holes in one region of the film stack, filling the holes with a second film, then etching the film stack and second layer to form a third hole in another region of the film stack and a fourth hole in the second layer in the second hole. The second layer is then removed. An insulating pillar portion is now formed in the first and second holes. A memory columnar portion is then formed in the third hole. The memory columnar portion includes a charge accumulation layer and a semiconductor layer. The sacrificial layers are then removed and replaced by electrode layers after the pillar and columnar portions have been formed.

### CROSS-REFERENCE TO RELATED APPLICATIONS

This application is based upon and claims the benefit of priority from Japanese Patent Application No. 2024-159618, filed Sep. 13, 2024, the entire contents of which are incorporated herein by reference.

### FIELD

Embodiments described herein relate generally to a method of manufacturing a semiconductor device.

### BACKGROUND

In forming a plurality of holes in a predetermined film for a three-dimensional semiconductor memory, some of the holes may not be appropriately formed. For example, when cryoetching is performed to form holes for both pillar portions to be located in a stepped portion of a film stack and columnar portions to be located in a non-stepped portion of the film stack, some holes for the columnar portions near the boundary between the stepped portion and the non-stepped portion might be formed inappropriately.

### BRIEF DESCRIPTION OF THE DRAWINGS

FIG. 1 is a cross-sectional view illustrating a structure of a semiconductor device according to a first embodiment.

FIG. 2 is an enlarged view illustrating a structure of a semiconductor device according to a first embodiment.

FIG. 3 is a plan view illustrating a structure of a semiconductor device according to a first embodiment.

FIGS. 4 to 13 each show a plan view and a corresponding cross-sectional view illustrating aspects of a method of manufacturing a semiconductor device according to a first embodiment.

FIG. 14 shows cross-sectional views illustrating aspects of a method of manufacturing a semiconductor device according to a first comparative example.

FIG. 15 shows cross-sectional views illustrating aspects of a method of manufacturing a semiconductor device according to a second comparative example.

FIG. 16 shows cross-sectional views illustrating aspects of a method of manufacturing a semiconductor device according to a third comparative example.

FIG. 17 is a cross-sectional view illustrating a structure of a semiconductor device according to a second embodiment.

FIG. 18 is a plan view illustrating a structure of a semiconductor device according to a second embodiment.

FIGS. 19 to 24 each show a plan view illustrating aspects of a method of manufacturing a semiconductor device according to a second embodiment.

FIG. 25 is a cross-sectional view illustrating a structure of a semiconductor device according to a third embodiment.

FIG. 26 is an enlarged view illustrating a structure of a semiconductor device according to a third embodiment.

FIGS. 27 and 28 each show a cross-sectional view illustrating aspects of a method of manufacturing a semiconductor device according to a third embodiment.

### DETAILED DESCRIPTION

A method of manufacturing a semiconductor device by which it is possible to suitably form holes in a predetermined film is described.

In general, according to one embodiment, a method of manufacturing a semiconductor device includes: forming a film stack that includes a plurality of first insulating films alternating with a plurality of first layers in a first direction. The film stack has a first region and a second region. A first hole and a second hole are formed in the second region. A second layer is then formed inside each of the first hole and the second hole. The method further includes etching the film stack and the second layer such that a third hole is formed in the first region and a fourth hole is formed in the second layer in the second hole of the second region. The second layer is then removed after the third hole and the fourth hole have been formed. A pillar portion is then formed in each of the first hole and the second hole. The pillar portion comprises a second insulating film. A columnar portion is formed in the third hole. The columnar portion comprises a charge accumulation layer and a semiconductor layer in the third hole. The plurality of first layers are then removed and replaced by a plurality of electrode layers after the pillar portion and the columnar portion have been formed.

Hereinafter, certain example embodiments of the present disclosure will be described with reference to the drawings. In the drawings and description, the aspects, elements, components, or the like that are substantially the same are denoted by the same reference symbols, and description of repeated aspects, elements, or components, may be omitted.

### First Embodiment

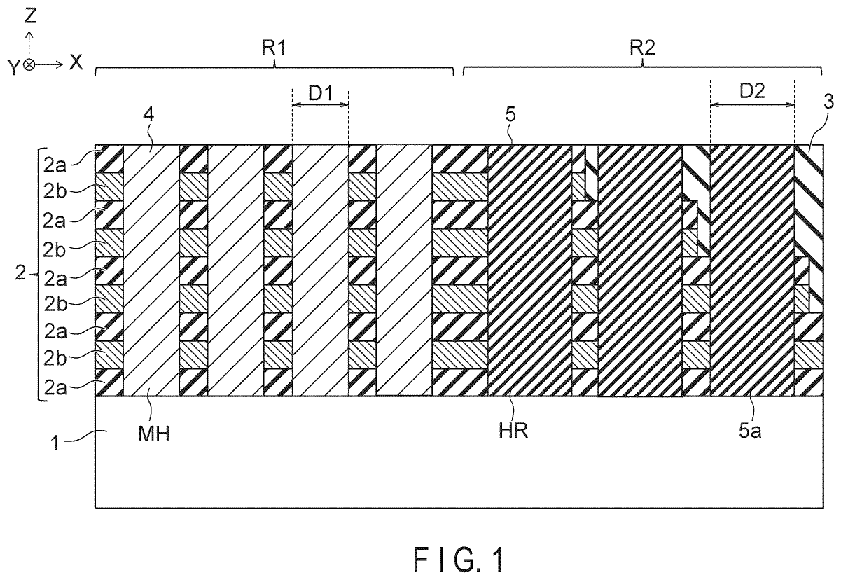

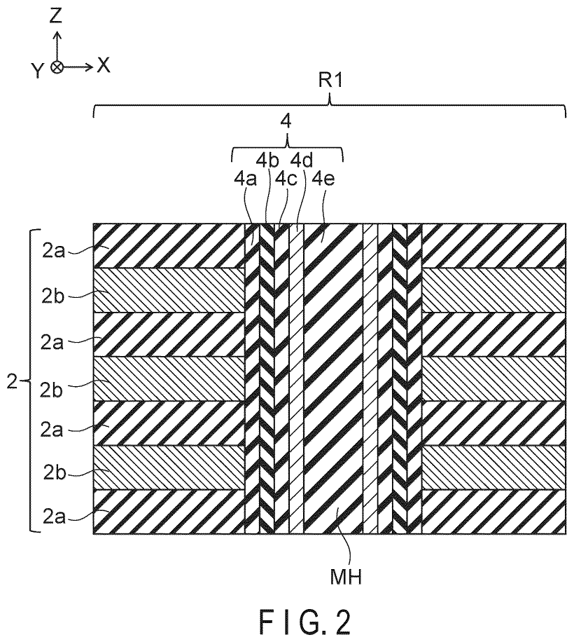

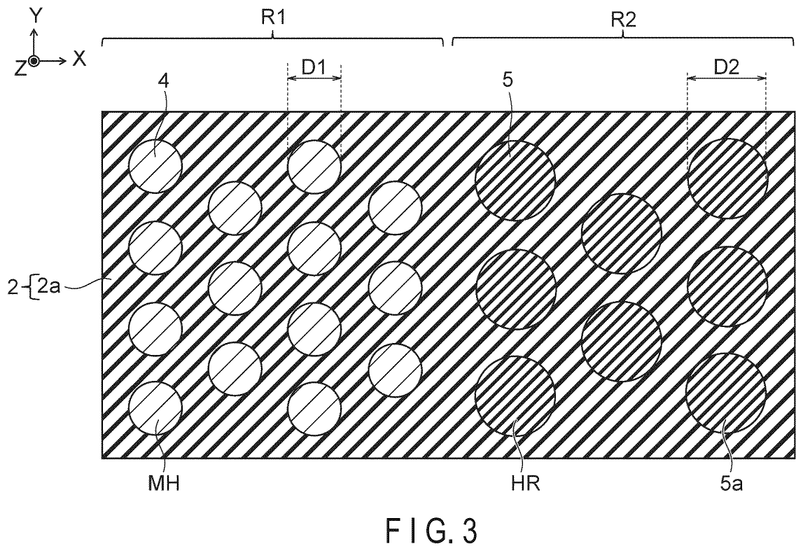

FIG. 1 is a cross-sectional view illustrating a structure of a semiconductor device according to a first embodiment. FIG. 2 is an enlarged cross-sectional view illustrating the structure of the semiconductor device according to the first embodiment. FIG. 3 is a plan view illustrating the structure of the semiconductor device according to the first embodiment.

The semiconductor device according to the present embodiment is, for example, a three-dimensional semiconductor memory. Hereinafter, a structure of the semiconductor device according to the present embodiment will be described mainly with reference to FIG. 1. In the description, FIG. 2 and FIG. 3 will also be referred to as needed.

The semiconductor device according to the present embodiment includes a substrate 1, a film stack 2, an inter-layer insulating film 3, a plurality of columnar portions 4, and a plurality of pillar portions (beam portions) 5. The film stack 2 includes a plurality of insulating films 2a and a plurality of electrode layers 2. Each columnar portion 4 includes a block insulating film 4a, a charge accumulation layer 4b, a tunnel insulating film 4c, a channel semiconductor layer 4d, and a core insulating film 4e (FIG. 2). Each pillar portion 5 includes an insulating film 5a. Each insulating film 2a in the film stack 2 is an example of the first insulating film. The insulating film 5a in each pillar portion 5 is an example of the second insulating film. The inter-layer insulating film 3 is an example of the third insulating film. The channel semiconductor layer 4d is an example of the semiconductor layer. The film stack 2 is an example of the first film.

The substrate 1 is a semiconductor substrate such as a silicon (Si) substrate, for example. FIG. 1 illustrates an X direction and a Y direction that are parallel to the surface of the substrate 1 and are perpendicular to each other and a Z direction that is perpendicular to the surface of the substrate 1. In the present specification, the +Z direction will be referred to as an upward direction, and the −Z direction will be referred to as a downward direction. The −Z direction may coincide with the gravity direction or may not. The Z direction is an example of a first direction. The X direction is an example of a second direction.

The film stack 2 is formed on the substrate 1 and alternately includes the plurality of insulating films 2a and the plurality of electrode layers 2b in the Z direction. Each insulating film 2a is, for example, a silicon oxide film (SiO₂ film). Each electrode layer 2b includes, for example, a metal layer such as a tungsten (W) layer. Each electrode layer 2b in the present embodiment functions as a word line or a select line of a three-dimensional semiconductor memory. The film stack 2 may be formed directly on the substrate 1 or may be formed above the substrate 1 via another film.

The film stack 2 includes a non-stepped portion (flat portion) R1 and a stepped portion R2. The non-stepped portion R1 has an upper surface with a non-stepped shape (flat shape). The stepped portion R2 has upper surfaces and side surfaces with a stepped shape. In FIG. 1, the stepped portion R2 is formed in the X direction relative to the non-stepped portion R1. The non-stepped portion R1 is an example of the first part. The stepped portion R2 is an example of the second part.

The inter-layer insulating film 3 is formed on the stepped portion R2 to eliminate height differences between the upper surface of the non-stepped portion R1 and the upper surfaces of the stepped portion R2. The inter-layer insulating film 3 is, for example, a tetraethyl orthosilicate (TEOS) film or a SiO₂ film.

FIG. 1 illustrates a plurality of memory holes MH formed in the non-stepped portion R1. Although the memory holes MH are disposed in a triangle grid shape in plan view (FIG. 3), the memory holes MH may be disposed in another grid shape. FIG. 3 illustrates an XY section of any of the insulating films 2a in the film stack 2. Each memory hole MH in the present embodiment has a circular shape with a diameter D1 in plan view. As illustrated in FIG. 1, each memory hole MH in the present embodiment extends in the Z direction, penetrates through the film stack 2 in the Z direction, and reaches the substrate 1. Each memory hole MH is an example of a third hole. The diameter D1 is an example of a second diameter.

Each columnar portion 4 is formed in a corresponding memory hole MH. Therefore, each columnar portion 4 in the present embodiment has a circular shape with the diameter D1 in plan view. Moreover, each columnar portion 4 in the present embodiment has a columnar shape extending in the Z direction, penetrates through the film stack 2 in the Z direction, and reaches the substrate 1.

Each columnar portion 4 includes a block insulating film 4a, a charge accumulation layer 4b, a tunnel insulating film 4c, a channel semiconductor layer 4d, and a core insulating film 4e formed in this order in a side surface of the film stack 2 as illustrated in FIG. 2. The block insulating film 4a is, for example, a SiO₂ film. The charge accumulation layer 4b is, for example, a silicon nitride film (SiN film). The charge accumulation layer 4b in the present embodiment can accumulate a signal charge of the three-dimensional semiconductor memory. The tunnel insulating film 4c is, for example, a SiO₂ film. The channel semiconductor layer 4d is, for example, a polysilicon layer. The channel semiconductor layer 4d in the present embodiment functions as channels of a plurality of cell transistors (memory cells) and a plurality of select transistors in the three-dimensional semiconductor memory. The core insulating film 4e is, for example, a SiO₂ film.

FIG. 1 illustrates a plurality of holes HR formed in the stepped portion R2 (or in the inter-layer insulating film 3 and the stepped portion R2). Although the holes HR are disposed in a triangle grid shape in plan view (FIG. 3), the holes HR may be disposed in another grid shape. Each hole HR in the present embodiment has a circular shape with a diameter D2 in plan view. In the present embodiment, the diameter D2 is greater than the diameter D1. As illustrated in FIG. 1, each hole HR in the present embodiment extends in the Z direction, penetrates through the film stack 2 (or the inter-layer insulating film 3 and the film stack 2) in the Z direction, and reaches the substrate 1. Each hole HR is an example of the first and second holes. The diameter D2 is an example of the first diameter.

Each pillar portion 5 is formed in a corresponding hole HR. Therefore, each pillar portion 5 in the present embodiment has a circular shape with the diameter D2 in plan view. Also, each pillar portion 5 in the present embodiment has a columnar shape extending in the Z direction, penetrates through the film stack 2 (or the inter-layer insulating film 3 and the film stack 2) in the Z direction, and reaches the substrate 1, similarly to each columnar portion 4.

Each pillar portion 5 includes an insulating film 5a as illustrated in FIG. 1. The insulating film 5a is, for example, a SiO₂ film. Each pillar portion (beam portion) 5 in the present embodiment functions as a pillar (beam) that prevents collapse of the film stack 2 during a replacement process or the like.

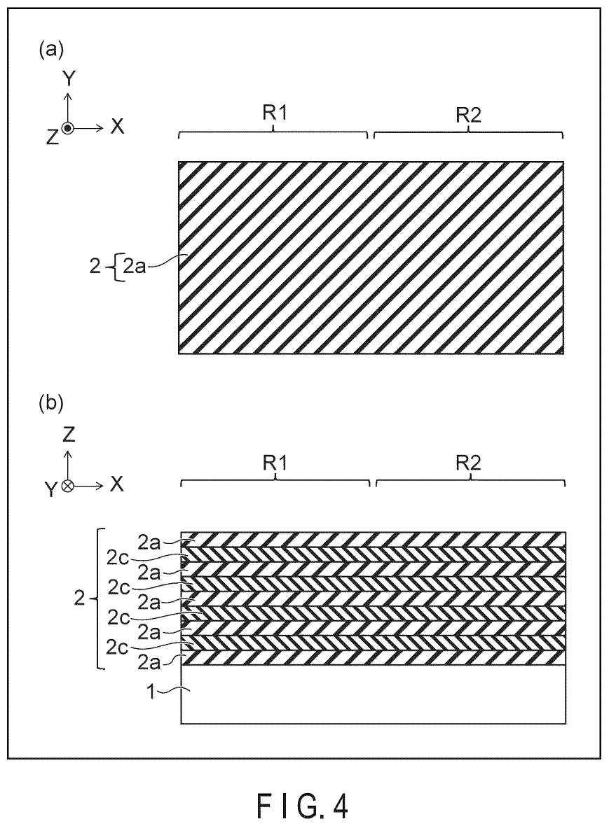

FIGS. 4 to 13 show plan views and cross-sectional views illustrating a method of manufacturing the semiconductor device according to the first embodiment.

First, a plurality of insulating films 2a and a plurality of sacrificial layers 2c are alternately formed on the substrate 1 to thereby form the film stack 2 on the substrate 1 (FIG. 4). As a result, the film stack 2 is formed to alternately include the plurality of insulating films 2a and the plurality of sacrificial layers 2c in the Z direction. Each sacrificial layer 2c is, for example, a SiN film. Each sacrificial layer 2c is an example of the first layer.

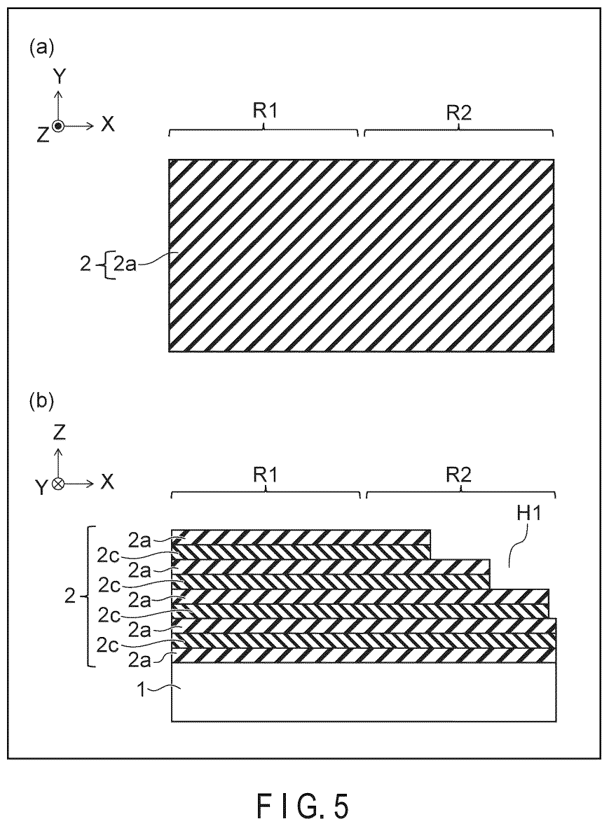

Next, a recessed portion H1 is formed in the film stack 2 through lithography and reactive ion etching (RIE) (FIG. 5). As a result, the non-stepped portion R1 and the stepped portion R2 are formed in the film stack 2.

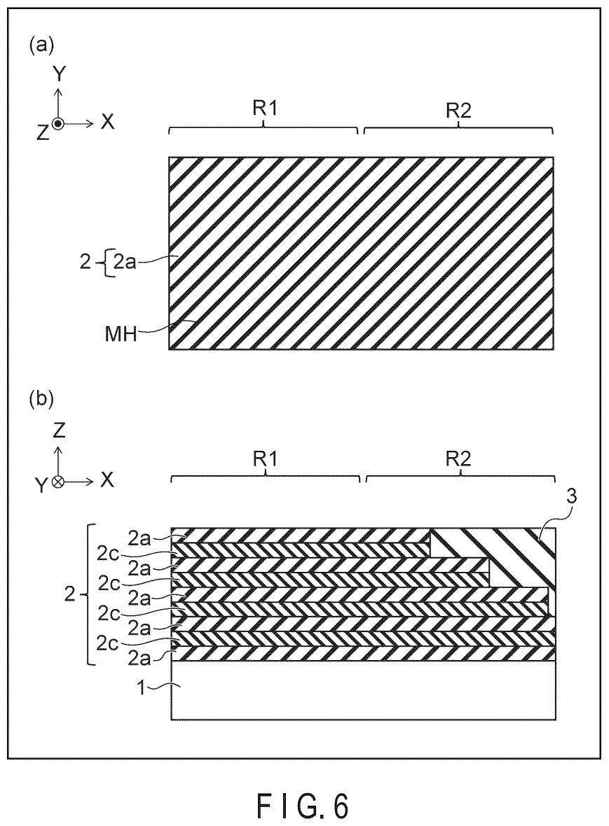

Next, the inter-layer insulating film 3 is formed on the stepped portion R2 (FIG. 6). As a result, the recessed portion H1 is filled with the inter-layer insulating film 3.

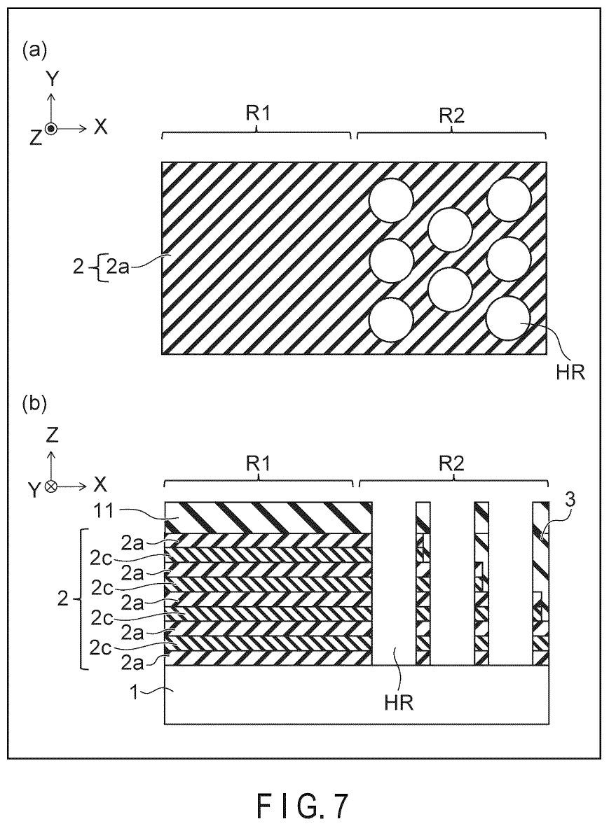

Next, a mask layer 11 is formed on the film stack 2, and the plurality of holes HR are formed in the mask layer 11 and the stepped portion R2 (or in the mask layer 11, the inter-layer insulating film 3, and the stepped portion R2) (FIG. 7) through lithography and RIE. Each hole HR in the present embodiment is formed to have a circular shape with the diameter D2 (see FIG. 1) in plan view. Also, each hole HR in the present embodiment is formed to extend in the Z direction and reach the substrate 1. The mask layer 11 is, for example, an advanced patterning film (APF).

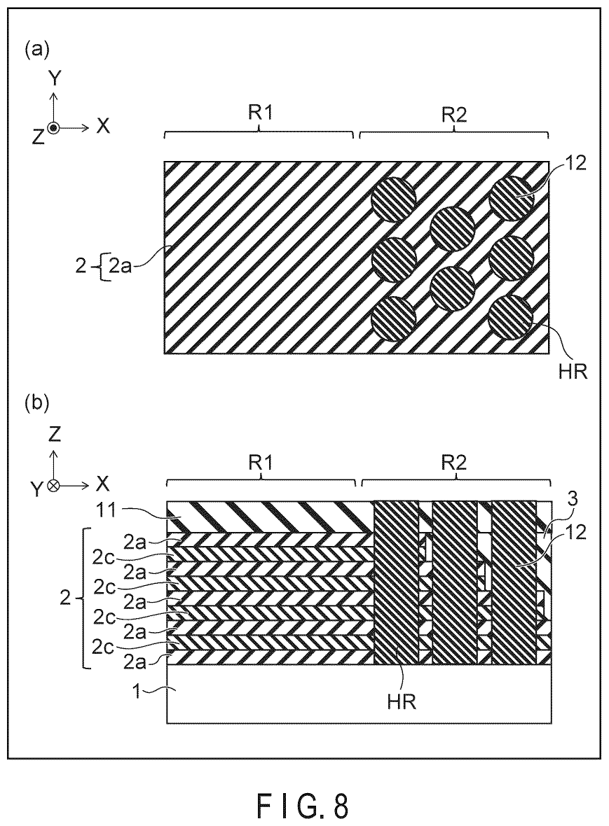

Next, sacrificial layers 12 are formed on the entire surface of the substrate 1 (FIG. 8). As a result, each sacrificial layer 12 is formed in each hole HR. The sacrificial layer 12 is, for example, a metal layer such as a tungsten (W) layer. The sacrificial layer 12 may be a metal layer other than the W layer or may be a non-metal layer such as a carbon (C) layer. Although it can be difficult to work the sacrificial layer 12 by cryoetching, it is desirable that the sacrificial layer 12 be formed of a material that can be easily removed otherwise. The sacrificial layer 12 is an example of a second layer.

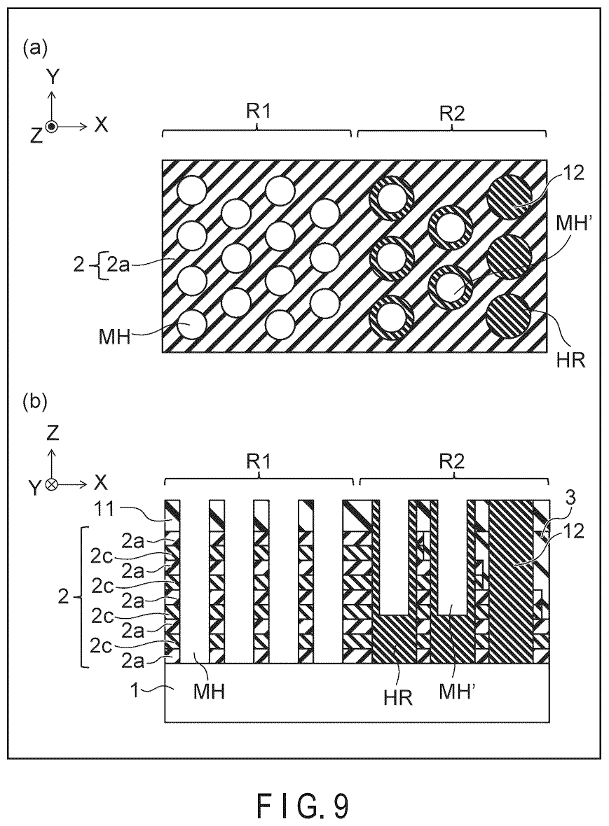

Next, the memory holes MH are formed in the mask layer 11 and the non-stepped portion R1 through lithography and dry etching (FIG. 9). Each memory hole MH in the present embodiment is formed to have a circular shape with the diameter D1 (see FIG. 1) in plan view. Also, each memory hole MH is formed to extend in the Z direction and reach the substrate 1.

The dry etching performed in the process illustrated in FIG. 9 is, for example, a cryoetching. In a cryoetching, the mask layer 11 and the film stack 2 are worked through etching at a low temperature using predetermined gas. Note that the process illustrated in FIG. 9 may be performed by an etching process other than cryoetching (for example, RIE).

The dry etching in the process illustrated in FIG. 9 is performed such that the plurality of memory holes MH are formed in the mask layer 11 and the non-stepped portion R1 and one or more dummy memory holes MH′ are formed in the sacrificial layers 12 in one or more holes HR. Each dummy memory hole MH′ is formed to have a circular shape with the diameter D1 in plan view similarly to each memory hole MH. While each dummy memory hole MH′ in the present embodiment is formed to extend in the Z direction, the dummy memory holes MH′ are formed not to reach all the way to the substrate 1. Therefore, each dummy memory hole MH′ illustrated in FIG. 9 does not penetrate completely through the sacrificial layer 12 in the Z direction. This can be realized by increasing an etching selectivity ratio between the film stack 2 and the sacrificial layer 12, for example. It is possible to prevent damage on the substrate 1 in the etching of each dummy memory hole MH′ by not penetrating through the sacrificial layer 12. Each dummy memory hole MH′ is an example of a fourth hole.

Each dummy memory hole MH′ in the present embodiment fails to penetrate both through the sacrificial layer 12 at the bottom of the hole HR and on the side surface of the hole HR as illustrated in FIG. 9. It is thus possible to prevent damage to the film stack 2 that might otherwise be due to the etching of each dummy memory hole MH′.

FIG. 9 illustrates a plurality of holes HR in the stepped portion R2. In the present embodiment, the dummy memory holes MH′ are formed in only some of the holes HR in the stepped portion R2. Specifically, the dummy memory holes MH′ are formed in the holes HR located close to the boundary between the non-stepped portion R1 and the stepped portion R2, but are not formed in the holes HR located far away from the boundary between the non-stepped portion R1 and the stepped portion R2. The holes HR in which dummy memory holes MH′ are formed are an example of second holes, and the holes HR in which dummy memory holes MH′ are not formed are an example of first holes. Note that the distance between a hole HR and the non-stepped portion R1 may be measured by any method, and may be considered to be the distance between a hole HR and the boundary between the non-stepped portion R1 and the stepped portion R2 or the distance between a hole HR and a central point of the non-stepped portion R1, for example.

When a plurality of memory holes MH are being formed in the non-stepped portion R1, the memory holes MH near the boundary between the non-stepped portion R1 and the stepped portion R2 may not form appropriately or similar to those away from the boundary. For example, the memory holes MH near the boundary may not completely penetrate through the film stack 2 as intended. The reason that such a phenomenon occurs around the boundary is considered to be because a region where the memory holes MH are formed (non-stepped portion R1) and a region where the memory holes MH are not formed (stepped portion R2) are switched around the boundary. Such a phenomenon occurs in a case where the memory holes MH are formed by cryoetching, for example.

Thus, the dry etching in the process illustrated in FIG. 9 is performed such that the plurality of memory holes MH are formed in the non-stepped portion R1 and the one or more dummy memory holes MH′ are formed near the boundary. As a result, the above phenomenon occurs near the boundary between the region where the memory holes MH or the dummy memory holes MH′ are formed and the region where the memory holes MH and the dummy memory holes MH′ are not formed instead of at the boundary between the region where the memory holes MH are formed (non-stepped portion R1) and the region where the memory holes MH are not formed (stepped portion R2). In this manner, it is possible to replace the holes that are not appropriately formed with the dummy memory holes MH′ from the memory holes MH and to thereby appropriately form the memory holes MH near the boundary between the non-stepped portion R1 and the stepped portion R2.

Note that providing a “dummy portion” where the dummy memory holes MH′ are to be formed between the non-stepped portion R1 and the stepped portion R2 is also conceivable. However, when the dummy portion is provided between the non-stepped portion R1 and the stepped portion R2, it is necessary to reduce the area available for the non-stepped portion R1 or the stepped portion R2 in plan view, or it is otherwise necessary to increase the area of the semiconductor device (semiconductor chip) in plan view (planar die area). However, according to the present embodiment, it is possible to avoid this problem with the area increase/utilization by forming dummy memory holes MH′ in the stepped portion R2 and then subsequently removing the dummy memory holes MH′.

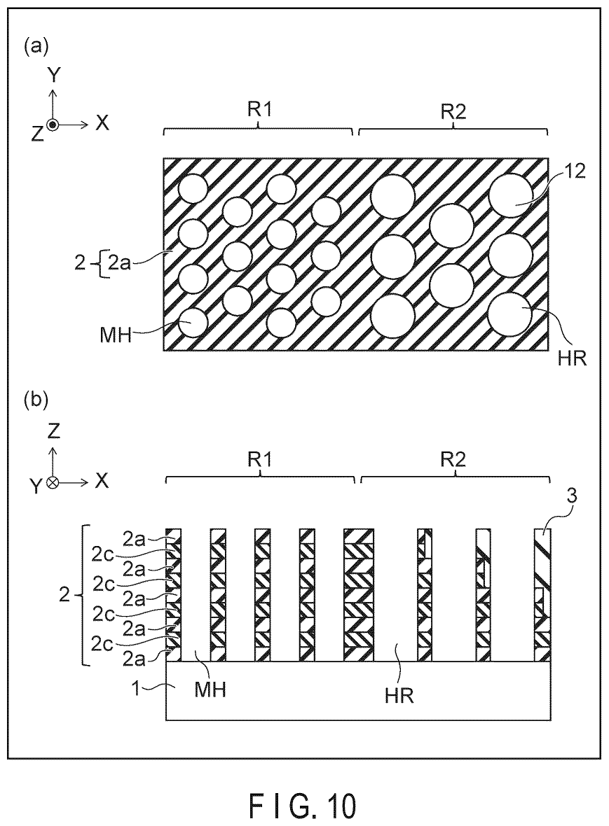

Next, the mask layer 11 and the sacrificial layer 12 are removed (FIG. 10). The mask layer 11 and the sacrificial layer 12 may be removed at the same time or may be removed in separate processes.

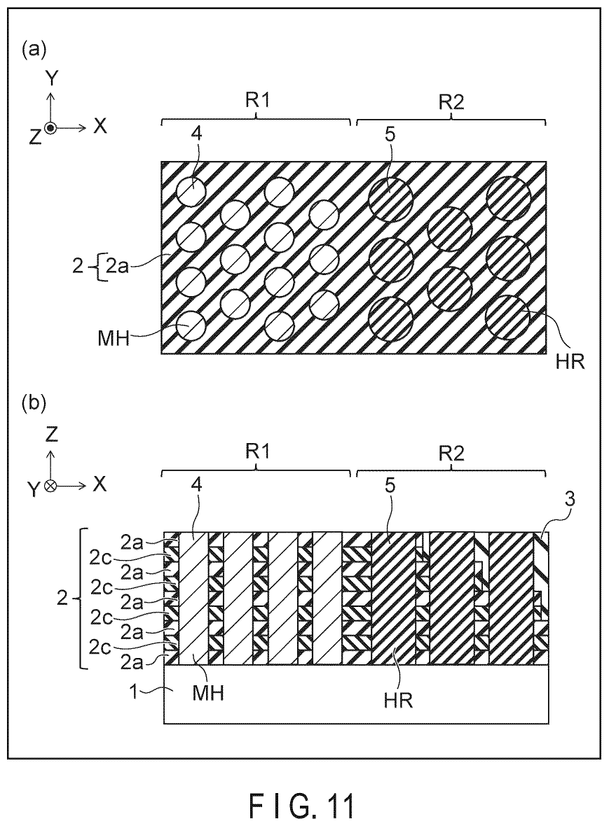

Next, the insulating film 5a is formed in each hole HR (FIG. 11). As a result, the pillar portion 5 is formed in each hole HR.

Next, the block insulating film 4a, the charge accumulation layer 4b, the tunnel insulating film 4c, the channel semiconductor layer 4d, and the core insulating film 4e are formed in order in each memory hole MH (FIG. 11). As a result, the columnar portion 4 is formed in each memory hole MH. Note that the columnar portion 4 may be formed before the pillar portion 5 is formed.

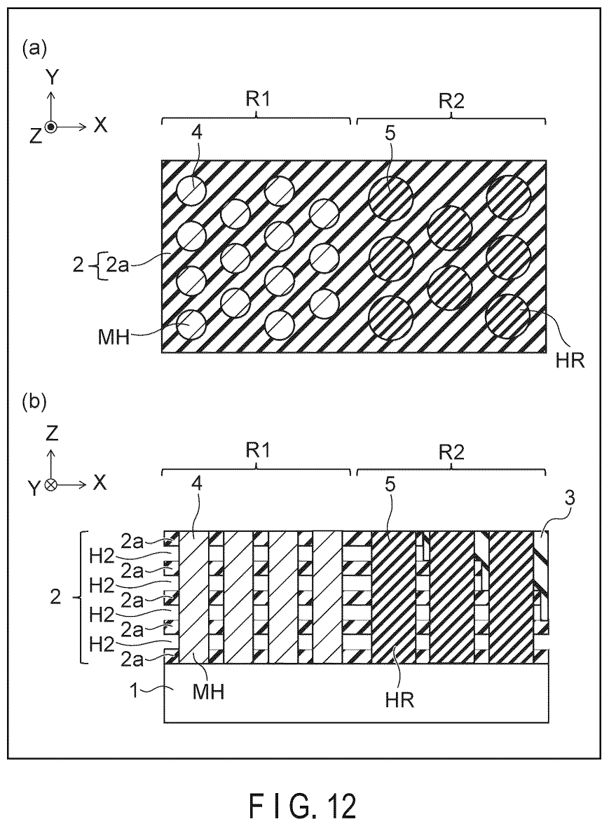

Next, a slit is formed in the film stack 2, and the plurality of sacrificial layers 2c are removed through wet etching via the slit (FIG. 12). As a result, a plurality of hollows H2 are formed in the film stack 2.

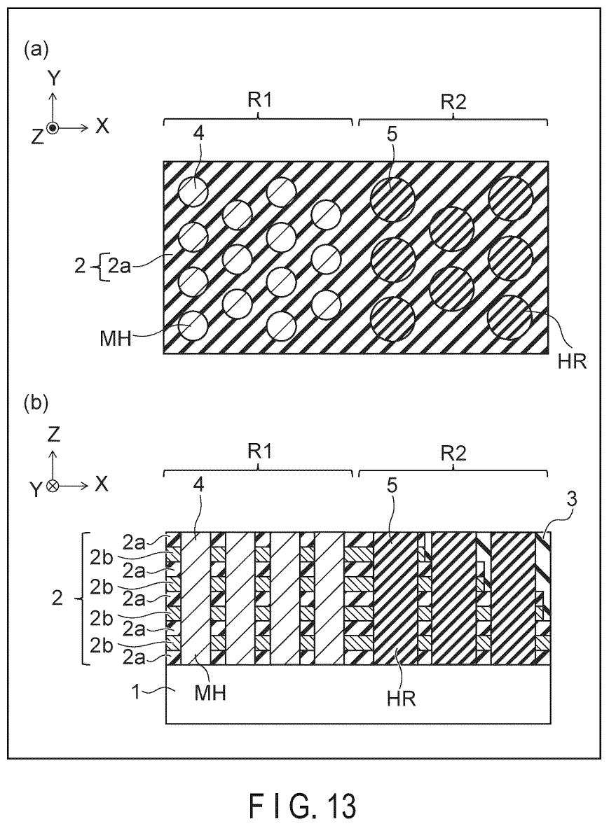

Next, the electrode layers 2b are formed in the hollows H2 (FIG. 13). In this manner, a replacement process of replacing the sacrificial layers 2c with electrode layers 2b is performed. Through the replacement process, the film stack 2 is worked to alternately include the plurality of insulating films 2a and the plurality of electrode layers 2b in the Z direction. Thereafter, various additional processes are performed to manufacture the semiconductor device illustrated in FIGS. 1 to 3.

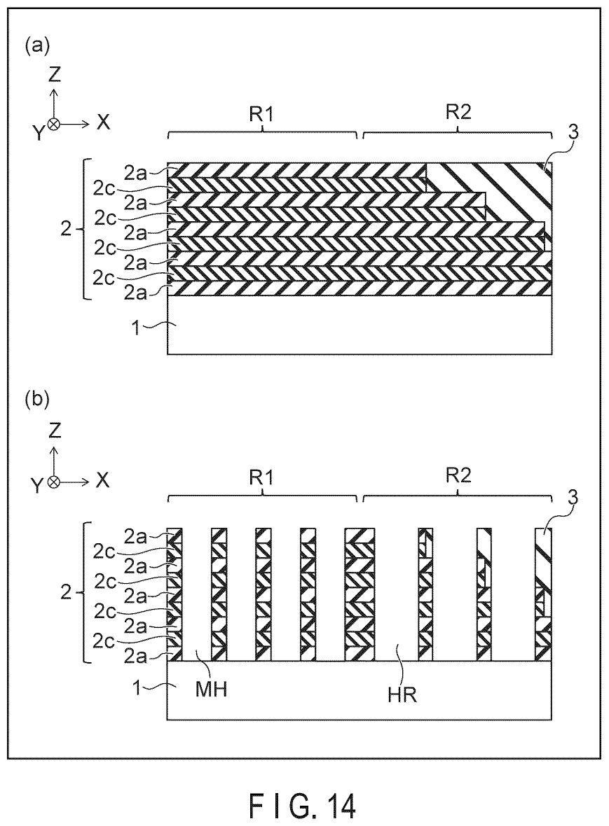

FIG. 14 is a cross-sectional view illustrating a method of manufacturing a semiconductor device according to a first comparative example.

First, the film stack 2 is formed on the substrate 1, the non-stepped portion R1 and the stepped portion R2 are formed in the film stack 2, and the inter-layer insulating film 3 is formed on the stepped portion R2 (part (a) of FIG. 14). Next, the plurality of holes HR are formed in the stepped portion R2 (or in the inter-layer insulating film 3 and the stepped portion R2), and the plurality of memory holes MH are formed in the non-stepped portion R1, by performing lithography and cryoetching (part (b) of FIG. 14).

In this first comparative example, the plurality of holes HR and the plurality of memory holes MH are formed at the same time through cryoetching. In a case where the insulating films 2a, the sacrificial layers 2c, and the inter-layer insulating film 3 are SiO₂ films, SiN films, and a TEOS film, respectively, it is typically not possible to etch the inter-layer insulating film 3 at a high speed although it is possible to etch the film stack 2 at a high speed through the cryoetching. Therefore, it is difficult to form the plurality of holes HR and the plurality of memory holes MH at the same time through the cryoetching.

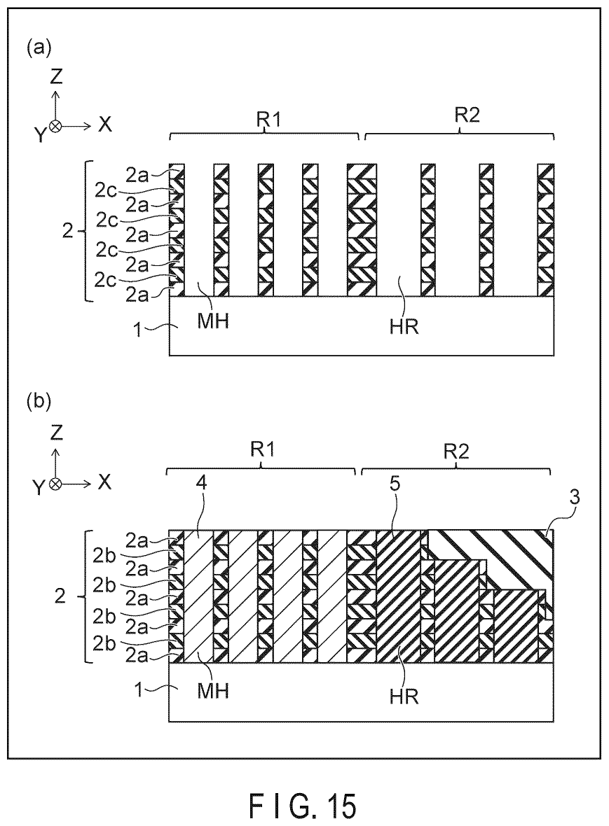

FIG. 15 is a cross-sectional view illustrating a method of manufacturing a semiconductor device according to a second comparative example.

First, the film stack 2 is formed on the substrate 1 (part (a) of FIG. 15). Next, the plurality of holes HR and the plurality of memory holes MH are formed in the film stack 2 by performing lithography and cryoetching (part (a) of FIG. 15). Each hole HR is formed in a region where the stepped portion R2 is to be formed, and each memory hole MH is formed in a region where the non-stepped portion R1 is to be formed.

Next, the pillar portion 5 is formed in each hole HR, and the columnar portion 4 is formed in each memory hole MH (part (b) of FIG. 15). As a result, the plurality of pillar portions 5 are formed in the region where the stepped portion R2 is to be formed, and the plurality of columnar portions 4 are formed in the region where the non-stepped portion R1 is to be formed. Next, the non-stepped portion R1 and the stepped portion R2 are formed by working the film stack 2 and some of the pillar portions 5, and the inter-layer insulating film 3 is formed on the stepped portion R2 and some of the pillar portions 5 (part (b) of FIG. 15).

In this second comparative example, the plurality of holes HR and the plurality of memory holes MH are formed at the same time through cryoetching before the non-stepped portion R1 and the stepped portion R2 are formed. In this manner, it is possible to avoid etching of the inter-layer insulating film 3, and it becomes easier to form the plurality of holes HR and the plurality of memory holes MH at the same time through cryoetching. However, the stepped portion R2 in this second comparative example is formed by working not only the film stack 2 but also the pillar portions 5, which leads to a processing difficulty.

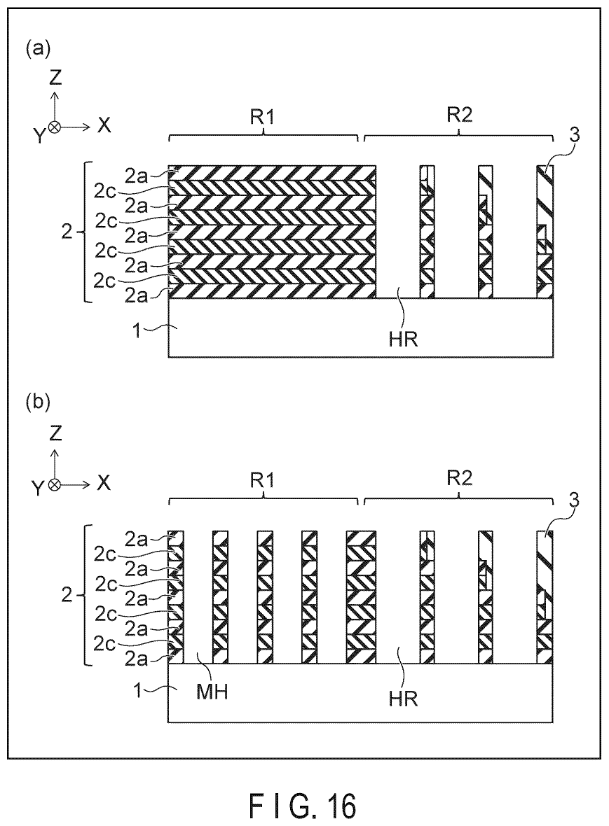

FIG. 16 is a cross-sectional view illustrating a method of manufacturing a semiconductor device according to a third comparative example.

First, the film stack 2 is formed on the substrate 1, the non-stepped portion R1 and the stepped portion R2 are formed in the film stack 2, and the inter-layer insulating film 3 is formed on the stepped portion R2 (part (a) of FIG. 16). Next, the plurality of holes HR are formed in the stepped portion R2 (or in the inter-layer insulating film 3 and the stepped portion R2) through lithography and RIE (part (a) of FIG. 16). Then, the memory holes MH are formed in the stepped portion R2 through lithography and cryoetching (part (b) of FIG. 16).

In this third comparative example, the plurality of holes HR are formed through RIE, and the plurality of memory holes MH are then formed through cryoetching. It is thus possible to avoid the problems of the first and second comparative examples. However, the memory holes MH may not be appropriately formed around the boundary between the non-stepped portion R1 and the stepped portion R2 in this third comparative example. Such a problem in the third comparative example can be avoided by incorporation of the dummy memory holes MH′ of the first embodiment as described above.

As described above, according to the first embodiment, etching is performed such that the plurality of memory holes MH are formed in the non-stepped portion R1 and the one or more dummy memory holes MH′ are formed in the sacrificial layers 12 in the one or more holes HR when the plurality of memory holes MH are formed through etching. Therefore, according to the present embodiment, it is possible to suitably form the memory holes MH in the film stack 2.

### Second Embodiment

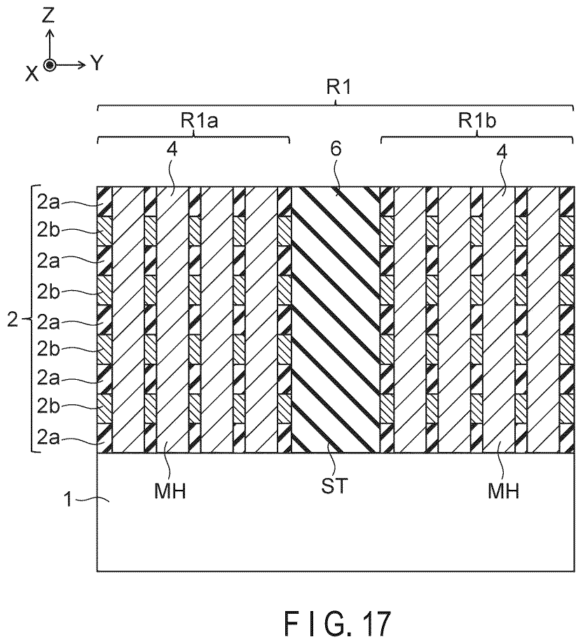

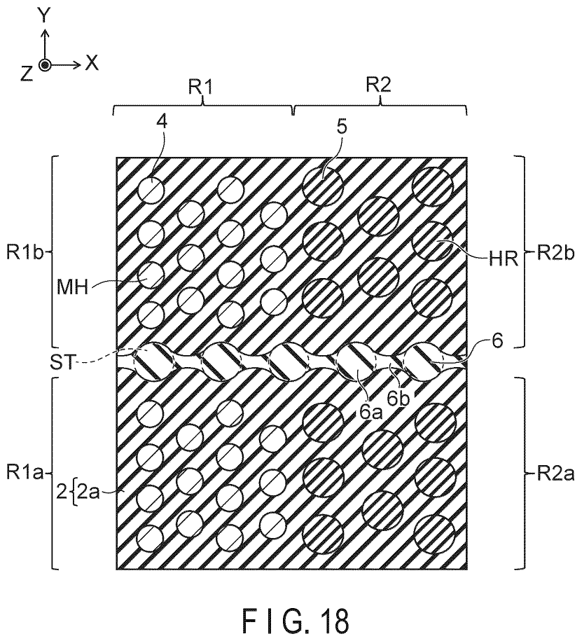

FIG. 17 is a cross-sectional view illustrating a structure of a semiconductor device according to a second embodiment. FIG. 18 is a plan view illustrating the structure of the semiconductor device according to the second embodiment.

The semiconductor device (FIGS. 17 and 18) according to the second embodiment includes a slit ST formed in a film stack 2 and an insulating film 6 formed in the slit ST in addition to components that are substantially similar to those in the semiconductor device according to the first embodiment. The insulating film 6 includes portions 6a and portions 6b as illustrated in FIG. 18. The slit ST is an example of a recessed portion.

While FIGS. 1 and 2 illustrate an XZ section of the semiconductor device according to the first embodiment, FIG. 17 illustrates a YZ section of the semiconductor device according to the second embodiment. Hereinafter, the structure of the semiconductor device according to the second embodiment will be described.

FIGS. 17 and 18 illustrate regions R1a and R1b in a non-stepped portion R1 and regions R2a and R2b in a stepped portion R2. The slit ST extends in the X direction and the Z direction, penetrates through the film stack 2 in the Z direction, and reaches a substrate 1. Specifically, the slit ST is successively formed in the non-stepped portion R1 and the stepped portion R2 and is formed between the region R1a and the region R1b and between the region R2a and the region R2b. The regions R1a and R2a form one finger portion in the film stack 2, and the regions R1b and R2b form another finger portion in the film stack 2.

The insulating film 6 extends in the X direction and the Z direction in the slit ST, penetrates through the film stack 2 in the Z direction, and reaches the substrate 1. The insulating film 6 is, for example, a SiO₂ film. The insulating film 6 alternately includes the portions 6a and the portions 6b in the X direction as illustrated in FIG. 18. Each portion 6a has a columnar shape extending in the Z direction, penetrates through the film stack 2 in the Z direction, and reaches the substrate 1. Similarly, each portion 6b has a columnar shape extending in the Z direction, penetrates through the film stack 2 in the Z direction, and reaches the substrate 1. The insulating film 6 is successively formed in the non-stepped portion R1 and the stepped portion R2 and is formed between the region R1a and the region R1b and between the region R2a and the region R2b.

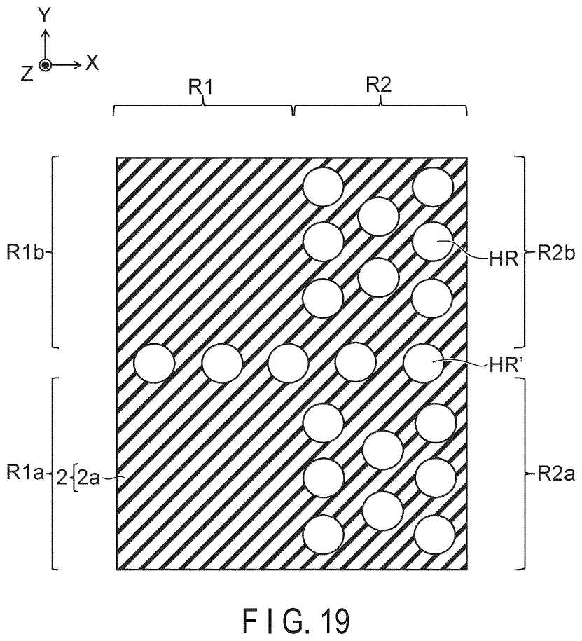

FIGS. 19 to 24 are plan views illustrating a method of manufacturing the semiconductor device according to the second embodiment. FIGS. 19 to 24 are plan views corresponding to FIG. 18.

First, processes illustrated in FIG. 4 through FIG. 7 are performed. However, in the process illustrated in FIG. 7, a mask layer 11 is formed on the film stack 2, and a plurality of holes HR and a plurality of dummy holes HR′ are formed in the mask layer 11 and the film stack 2 through lithography and RIE as depicted in FIG. 19. Each dummy hole HR′ in the second embodiment is formed to have a circular shape with a diameter D2 (see FIG. 3) in plan view similarly to each hole HR. Also, each dummy hole HR′ in the second embodiment is formed to extend in the Z direction and reach the substrate 1 similarly to each hole HR. In FIG. 19, the plurality of dummy holes HR′ are formed between the region R1a and the region R1b and between the region R2a and the region R2b and are spaced apart from each other in the X direction. Each dummy hole HR′ is an example of a fifth hole.

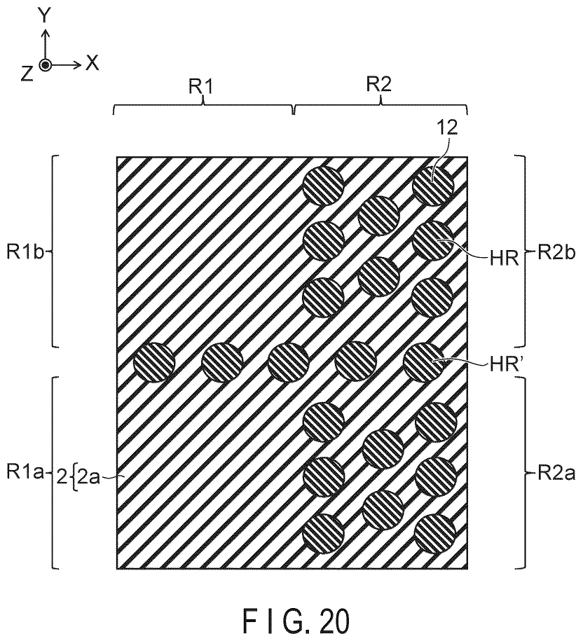

Next, in a process as illustrated in FIG. 8, sacrificial layers 12 are formed over the entire surface of the substrate 1, though in the manner corresponding to FIG. 20. As a result, the sacrificial layer 12 is formed in each hole HR and each dummy hole HR′.

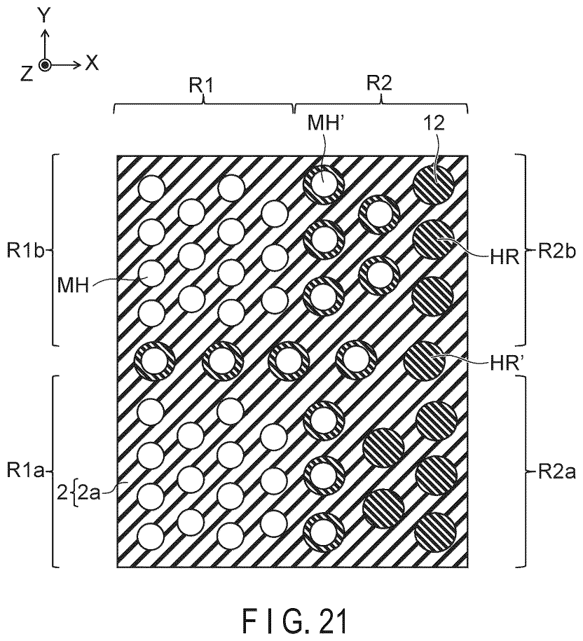

Next, in the process illustrated in FIG. 9, a plurality of memory holes MH are formed in the mask layer 11 and the film stack 2 through lithography and dry etching in the manner corresponding to FIG. 21. The dry etching is, for example, cryoetching as described above. The dry etching is performed such that memory holes MH are formed in the non-stepped portion R1, one or more dummy memory holes MH′ are formed in the sacrificial layers 12 in one or more holes HR, and one or more dummy memory holes MH′ are formed in the sacrificial layers 12 in one or more dummy holes HR′. Hereinafter, dummy memory holes MH′ formed in the memory holes HR will be referred to as “dummy memory hole MH′[HR]”, and dummy memory holes MH′ formed in the dummy memory holes HR′ will be referred to as “dummy memory holes MH′[HR′]”. In FIG. 21, the dummy memory holes MH′[HR] are formed only in some of the holes HR, and the dummy memory holes MH′[HR′] are also formed only in some of the dummy holes HR′. The dummy memory holes MH′[HR′] are an example of a sixth hole.

Each dummy memory hole MH′[HR′] in the second embodiment is formed to have a circular shape with the diameter D1 (see FIG. 3) in plan view similarly to each memory hole MH and each dummy memory hole MH′[HR]. Also, each dummy memory hole MH′[HR′] in the second embodiment is formed not to penetrate through the sacrificial layers 12 formed on a bottom and side surface of the dummy hole HR′ similarly to each dummy memory hole MH′[HR].

In a case where the plurality of memory holes MH are formed in the non-stepped portion R1, the memory holes MH might not be appropriately formed near the boundary between the regions R1a and R2a and the regions R1b and R2b. The reason is similar to that when the memory holes MH are not appropriately formed near the boundary between the non-stepped portion R1 and the stepped portion R2. Thus, the dry etching is performed such that one or more dummy memory holes MH′[HR′] are formed near the boundary between the regions R1a and R2a and the regions R1b and R2b. It is thus possible to appropriately form the memory holes MH around the boundary between the regions R1a and R2a and the regions R1b and R2b as well. Note that the dummy memory holes MH′[HR′] are formed in the dummy holes HR′ provided in the region R1 and in the dummy holes HR′ provided in the region R2 around the region R1.

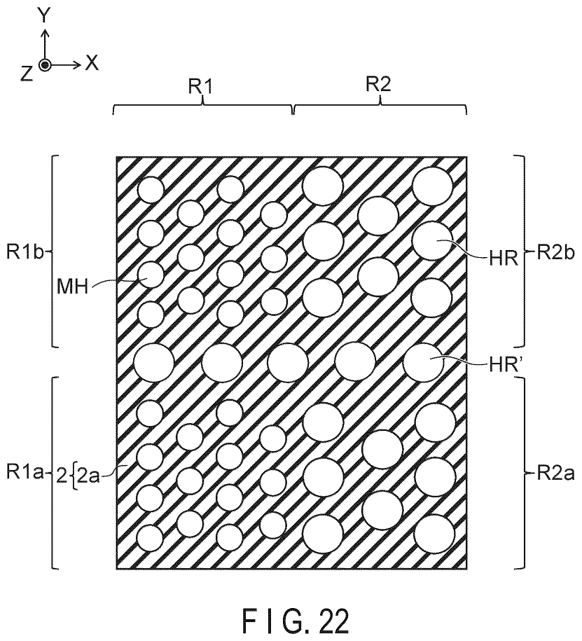

Next, in the process illustrated in FIG. 10, the mask layer 11 and the sacrificial layers 12 are removed in a manner corresponding to FIG. 22.

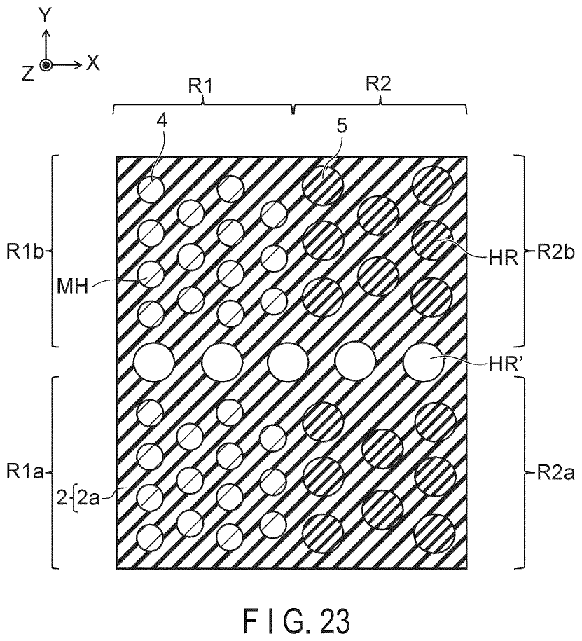

Next, in the process illustrated in FIG. 11, the insulating film 5a is formed in each hole HR in the manner corresponding to FIG. 23. As a result, a pillar portion 5 is formed in each hole HR. Next, in the process illustrated in FIG. 11, a block insulating film 4a, a charge accumulation layer 4b, a tunnel insulating film 4c, a channel semiconductor layer 4d, and a core insulating film 4e are formed in order in each memory hole MH in a manner corresponding to FIG. 23. As a result, a columnar portion 4 is formed in each memory hole MH.

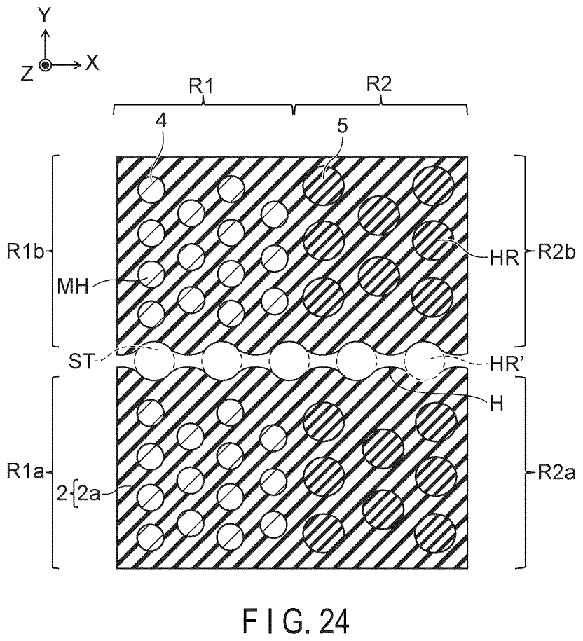

Next, in the process illustrated in FIG. 12, the slit ST is formed in the film stack 2, and the plurality of sacrificial layers 2c are removed through wet etching via the slit ST in a manner corresponding to FIG. 24. When the slit ST is formed, a plurality of holes H are formed between the dummy holes HR′ through wet etching from the plurality of dummy holes HR′. As a result, the plurality of dummy holes HR′ are connected to each other by these holes H. The slit ST in the second embodiment is formed to alternately include dummy holes HR′ and holes H along the X direction.

Next, the process illustrated in FIG. 13 is performed. Furthermore, the insulating film 6 is formed in the slit ST. In this manner, the semiconductor device illustrated in FIGS. 17 and 18 is manufactured. Note that each portion 6a represents a part of the insulating film 6 formed in one dummy hole HR′ and each portion 6b represents a part of the insulating film 6 formed in one hole H (see FIG. 18).

Note that the slit ST in the second embodiment may be formed to have a shape other than the particular shape illustrated in FIG. 24. For example, each hole H may be formed to have a shape other than the shape illustrated in FIG. 24.

In addition, a plurality of slits ST may be formed in the film stack 2. In this case, the slit ST illustrated in FIGS. 17 to 24 corresponds to at least one of the plurality of slits ST.

As described above, according to the second embodiment, etching is performed such that the plurality of memory holes MH are formed in the non-stepped portion R1 and the one or more dummy memory holes MH′[HR′] are formed in the sacrificial layers 12 in the one or more dummy holes HR′ when the plurality of memory holes MH are formed through the etching. Therefore, according to the second embodiment, it is possible to suitably form the memory holes MH in the film stack 2.

Note that in a case where the semiconductor device according to the first or second embodiment is manufactured by attaching the substrate 1 to another substrate, the completed semiconductor device need not include the substrate 1 as a final component. An example of such a semiconductor device will be described in a third embodiment.

### Third Embodiment

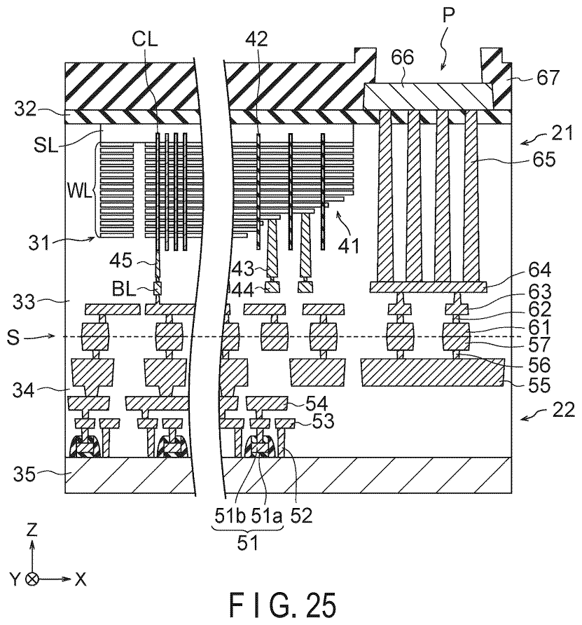

FIG. 25 is a cross-sectional view illustrating a structure of a semiconductor device according to the third embodiment. The semiconductor device according to the third embodiment is, for example, a three-dimensional semiconductor memory.

The semiconductor device according to the third embodiment includes an array chip 21 and a circuit chip 22 that are attached to each other. The semiconductor device according to the third embodiment is manufactured by attaching an array wafer including the array chip 21 to a circuit wafer including the circuit chip 22.

The array chip 21 includes a memory cell array 31 including a plurality of memory cells, an insulating film 32 above the memory cell array 31, and an inter-layer insulating film 33 below the memory cell array 31. The insulating film 32 is, for example, a SiO₂ film. The inter-layer insulating film 33 is, for example, a film stack that includes a SiO₂ film and another insulating film. A part of the memory cell array 31 in the third embodiment corresponds to the film stack 2 in the first or second embodiment.

The circuit chip 22 is provided below the array chip 21. The reference sign S denotes an attachment plane (interface region) between the array chip 21 and the circuit chip 22. The circuit chip 22 includes an inter-layer insulating film 34 below the inter-layer insulating film 33 and a substrate 35 below an inter-layer insulating film 34. The inter-layer insulating film 34 is, for example, a film stack that includes a SiO₂ film and another insulating film. The substrate 35 is, for example, a semiconductor substrate such as a silicon substrate.

The array chip 21 includes a plurality of word lines WL (electrode layers) in the memory cell array 31. FIG. 25 illustrates a stepped structure portion 41 in the memory cell array 31 and a plurality of pillar portions 42 provided in the stepped structure portion 41. Pillar portions 42 may be referred to in some contexts as beam portions, support structures, or the like. Each word line WL extends in the X direction and is electrically connected to a word wiring layer 44 via a contact plug 43. Each columnar portion CL penetrating through the plurality of word lines WL is electrically connected to a bit line BL via a via plug 45 and is electrically connected to a source line SL. The bit line BL extends in the Y direction and is provided below the plurality of word lines WL. The source line SL extends in the X direction and is provided above the plurality of word lines WL. The stepped structure portion 41, the pillar portions 42, the columnar portions CL, and the word lines WL in the present embodiment correspond to the stepped portion R2, the pillar portions 5, the columnar portions 4, and the electrode layers 2b in the first or second embodiment, respectively.

The circuit chip 22 includes a plurality of transistors 51. Each transistor 51 includes a gate insulating film 51a and a gate electrode 51b that are provided in order on the substrate 35 and a source diffusion layer and a drain diffusion layer that are provided in the substrate 35. Also, the circuit chip 22 includes a plurality of contact plugs 52 provided on the gate electrodes 51b, the source diffusion layers, or the drain diffusion layers of the plurality of transistors. The circuit chip 22 includes a wiring layer 53, a wiring layer 54, and a wiring layer 55. The wiring layer 53 includes a plurality of wirings and is provided on the plurality of contact plugs 52. The wiring layer 54 includes a plurality of wirings and is provided on the wiring layer 53. The wiring layer 55 includes a plurality of wirings and is provided on the wiring layer 54.

The circuit chip 22 further includes a plurality of via plugs 56 provided on the wiring layer 55 and a plurality of metal pads 57 provided on the plurality of via plugs 56. The metal pads 57 are, for example, metal layers including copper (Cu) layers. The circuit chip 22 functions as a logic circuit that controls operations of the array chip 21. The logic circuit is configured by the transistors 51 and is electrically connected to the metal pads 57.

The array chip 21 includes a plurality of metal pads 61 provided on the plurality of metal pads 57 and a plurality of via plugs 62 provided on the plurality of metal pads 61. The metal pads 61 are, for example, metal layers including Cu layers. Also, the array chip 21 includes a wiring layer 63 and a wiring layer 64. The wiring layer 63 includes a plurality of wirings and is provided on the plurality of via plugs 62. The wiring layer 64 includes a plurality of wirings and is provided on the wiring layer 63. The bit lines BL are included in the wiring layer 64. Also, the logic circuit is electrically connected to the memory cell array 31 via the metal pads 61 and 57 and the like and controls operations of the memory cell array 31 via the metal pads 61 and 57 and the like.

The array chip 21 further includes a plurality of via plugs 65 provided on the wiring layer 64 and a metal pad 66 provided on the plurality of via plugs 65 and the insulating film 32. Also, the array chip 21 includes a passivation insulating film 67 provided on the metal pad 66 and the insulating film 32. The metal pad 66 is, for example, a metal layer including a Cu layer and functions as an external connection pad (bonding pad) of the semiconductor device according to the third embodiment. The passivation insulating film 67 is, for example, a film stack including a SiO₂ film and a SiN film and has an opening portion P at which an upper surface of the metal pad 66 is exposed. The metal pad 66 can be electrically connected to a mounted substrate or another device with a bonding wire, a solder ball, a metal bump, or the like via the opening portion P.

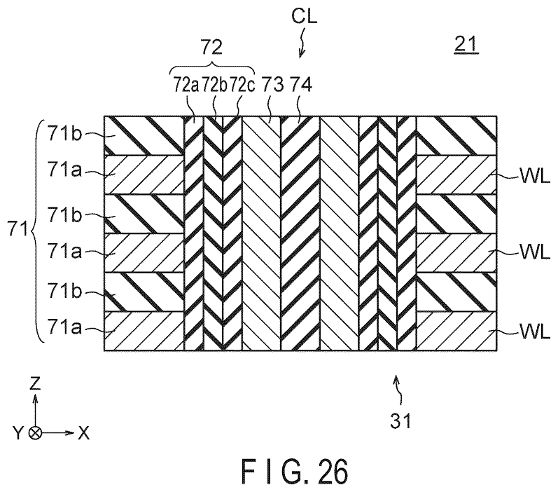

FIG. 26 is an enlarged cross-sectional view illustrating the structure of the semiconductor device according to the third embodiment.

FIG. 26 illustrates the memory cell array 31 illustrated in FIG. 25. The memory cell array 31 includes a film stack 71 including a plurality of electrode layers 71a and a plurality of insulating films 71b alternately stacked in the Z direction. The plurality of electrode layers 71a function as the word lines WL, for example. Each electrode layer 71a includes, for example, a metal layer such as a tungsten (W) layer. Each insulating film 71b is, for example, a SiO₂ film. The film stack 71, the electrode layers 71a, and the insulating films 71b in the present embodiment correspond to the film stack 2, the electrode layers 2b, and the insulating films 2a in the first or second embodiments, respectively.

FIG. 26 further illustrates one of the plurality of columnar portions CL illustrated in FIG. 25. Each columnar portion CL includes a memory insulating film 72, a channel semiconductor layer 73, and a core insulating film 74 provided in order in a side surface of the film stack 71. The memory insulating film 72 includes a block insulating film 72a, a charge accumulation layer 72b, and a tunnel insulating film 72c provided in order in the side surface of the film stack 71. The block insulating film 72a is, for example, a SiO₂ film. The charge accumulation layer 72b is, for example, an insulating film such as a SiN film. The charge accumulation layer 72b may be a semiconductor layer such as a polysilicon layer. The charge accumulation layer 72b can accumulate signal charges for a three-dimensional semiconductor memory transistor or the like. The tunnel insulating film 72c is, for example, a SiO₂ film. The channel semiconductor layer 73 is, for example, a polysilicon layer. The channel semiconductor layer 73 functions as a channel of the three-dimensional semiconductor memory. The core insulating film 74 is, for example, a SiO₂ film. The block insulating film 72a, the charge accumulation layer 72b, the tunnel insulating film 72c, the channel semiconductor layer 73, and the core insulating film 74 in the third embodiment correspond to the block insulating film 4a, the charge accumulation layer 4b, the tunnel insulating film 4c, the channel semiconductor layer 4d, and the core insulating film 4e in the first or second embodiment, respectively.

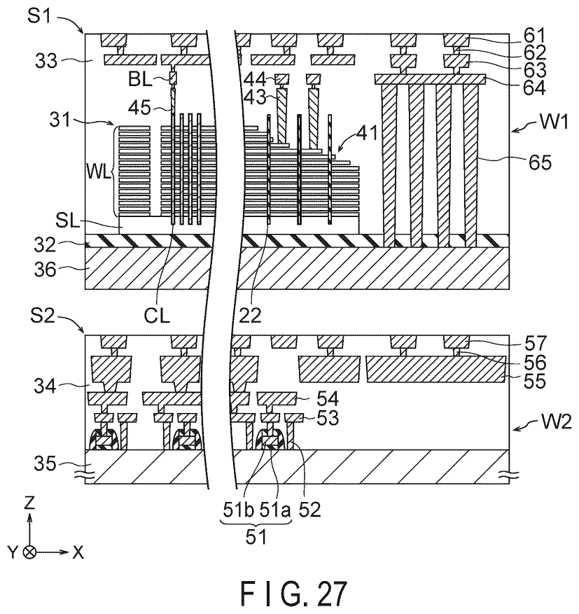

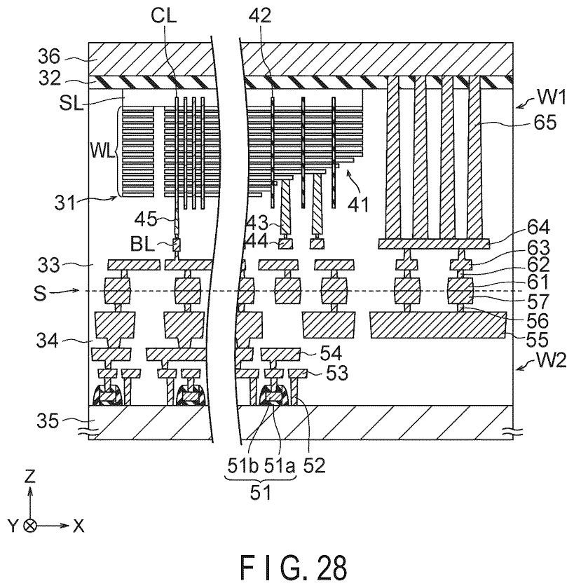

FIGS. 27 and 28 are cross-sectional views illustrating a method of manufacturing the semiconductor device according to the third embodiment.

FIG. 27 illustrates an array wafer W including a plurality of array chips 21 and a circuit wafer W2 including a plurality of circuit chips 22. The orientation of the array wafer W1 in FIG. 27 is opposite to the orientation of the array chip 21 depicted in FIG. 25. In the third embodiment, the semiconductor device is manufactured by attaching the array wafer W1 and the circuit wafer W2. FIG. 27 illustrates the array wafer W1 before the orientation is inverted for the attachment, and FIG. 25 illustrates the array chip 21 after the orientation has been inverted for the attachment and the attachment and dicing performed.

In FIG. 27, the reference sign S1 denotes an upper surface of the array wafer W1, and the reference sign S2 denotes an upper surface of the circuit wafer W2. The array wafer W1 includes a substrate 36 provided below the insulating film 32. The substrate 36 is, for example, a semiconductor substrate such as a silicon (Si) substrate. The substrate 36 in the third embodiment corresponds to the substrate 1 in the first or second embodiment.

In the third embodiment, the memory cell array 31, the insulating film 32, the inter-layer insulating film 33, the metal pads 61, the via plugs 65, and the like are formed on the substrate 36 of the array wafer W1, and the inter-layer insulating film 34, the transistors 51, the metal pads 57, and the like are formed on the substrate 35 of the circuit wafer W2, as illustrated in FIG. 27 first. Next, the array wafer W1 and the circuit wafer W2 are attached to each other with a mechanical pressure applied while the surface S1 and the surface S2 face each other as illustrated in FIG. 28. In this manner, the inter-layer insulating film 33 and the inter-layer insulating film 34 are bonded. Next, the array wafer W1 and the circuit wafer W2 are annealed. In this manner, the metal pads 61 and the metal pads 57 are joined. In this manner, the substrate 36 and the substrate 35 are attached to each other via the inter-layer insulating films 33 and 34.

Thereafter, the substrate 36 may be removed through chemical mechanical polishing (CMP), the substrate 35 is also thinned through CMP, and the array wafer W1 and the circuit wafer W2 are then cut into a plurality of chips (dicing). In this manner, the semiconductor device illustrated in FIG. 25 is manufactured. Note that the metal pad 66 and the passivation insulating film 67 are formed on the insulating film 32 after the removal of the substrate 36 and the thinning of the substrate 35.

Note that although FIG. 25 illustrates a boundary surface between the inter-layer insulating film 33 and the inter-layer insulating film 34 and a boundary surface between the metal pads 61 and the metal pads 57, however, these boundary surfaces are typically not readily observable after the annealing process. However, the positions where the boundary surfaces had been located may be estimated by detecting differences in inclination of the side surfaces of the metal pads 61 and the side surfaces of the metal pads 57 and/or positional deviation between the side surfaces of the metal pads 61 and the side surfaces of the metal pads 57, for example.

It is possible to apply semiconductor devices and the method of manufacturing a semiconductor device according to the first or second embodiment to the third embodiment.

While certain embodiments have been described, these embodiments have been presented by way of example only and are not intended to limit the scope of the present disclosure. Indeed, the novel devices and methods described herein may be embodied in a variety of other forms; furthermore, various omissions, substitutions, and changes in the form of the embodiments described herein may be made without departing from the spirit of the disclosure. The accompanying claims and their equivalents are intended to cover such forms or modification as would fall within the scope and spirit of the disclosure.

What is claimed is

1. A method of manufacturing a semiconductor device, the method comprising:
forming a film stack that includes a plurality of first insulating films alternating with a plurality of first layers along a first direction, the film stack having a first region and a second region;
forming first hole and a second hole in the second region;
forming a second layer in the first hole and the second hole;
etching the film stack and the second layer such that a third hole is formed in the first region of the film stack and a fourth hole is formed in the second layer in the second hole;
removing the second layer after the third hole and the fourth hole have been formed;
forming a pillar portion in each of the first hole and the second hole, the pillar portion including a second insulating film;
forming a columnar portion in the third hole, the columnar portion including a charge accumulation layer and a semiconductor layer; and
removing the plurality of first layers and forming a plurality of electrode layers in place of the plurality of first layers after the pillar portion and the columnar portion have been formed.

2. The method of claim 1, wherein
the first region is a non-stepped region of the film stack; and
the second region is a stepped region of the film stack.

3. The method of claim 2, further comprising:
forming a third insulating film on the stepped region before the first holes and the second holes are formed, wherein
the first holes out are formed in the stepped region and the third insulating film.

4. The method of claim 1, wherein the second holes are closer to the first region than are the first holes.

5. The method of claim 1, wherein
the first holes and the second holes each have a first diameter in plan view, and
the third holes and the fourth holes each have a second diameter that is less than the first diameter in plan view.

6. The method of claim 1, wherein the first holes and the second holes are formed to penetrate entirely through the film stack.

7. The method of claim 1, wherein
the third holes are formed to penetrate entirely through the film stack, and
the fourth holes are formed not to penetrate entirely through the second layer.

8. The method of claim 1, wherein the second layer is a metal layer.

9. The method of claim 8, wherein the second layer is a tungsten layer.

10. The method of claim 1, wherein the second layer is a carbon layer.

11. The method of claim 1, wherein the etching of the film stack and the second layer comprises a cryoetching process.

12. The method of claim 1, further comprising:
forming a slit portion in the film stack after the pillar portion and the columnar portion having been formed, wherein
the removing of the plurality of first layers and forming of the plurality of electrode layers is performed via the slit portion.

13. The method of claim 12, wherein the slit portion is formed crossing both the first region and the second region.

14. The method of claim 12, wherein
the second region is formed adjacent to the first region in a second direction, and
the slit portion extends in the second direction from the second region to the first region.

15. The method of claim 12, further comprising:
forming a plurality of fifth holes in the film stack, wherein
the slit portion is formed by connecting the plurality of fifth holes.

16. The method of claim 15, wherein the plurality of fifth holes are formed in the etching to form the first holes and the second holes.

17. The method of claim 15, wherein the second layer is formed in each of the first holes, the second holes, and the fifth holes.

18. The method of claim 15, wherein the etching of the film stack and the second layer is performed such that the third holes are formed in the first region, the fourth holes are formed in the second layer in the second holes, and a sixth hole is formed in the second layer in at least one fifth hole from among the plurality of fifth holes.

19. A method of manufacturing a semiconductor device, the method comprising:
forming a first film having a first region adjacent to a second region;
etching a first hole and a second hole in the second region of the first film;
filling each of the first hole and the second hole with a second film;
forming a third hole in the first region and a fourth hole inside the second hole by etching the first film and the second film while leaving the second film in the first hole;
removing the second film after forming the third hole and the fourth hole;
forming a pillar portion in each of the first hole and the second hole after removing the second film, the pillar portion comprising an insulating film; and
forming a columnar portion in the third hole, the columnar portion comprising a charge accumulation layer and a semiconductor layer.

20. The method of manufacturing a semiconductor device of claim 19, wherein
the first film is a film stack including a plurality of first insulating films alternating with a plurality of sacrificial layers along a first direction, and
the method further comprises:
removing the plurality of sacrificial layers and forming electrode layers in place of the removed sacrificial layers after the pillar portion and the columnar portion are formed.
